(19) United States
(12) Patent Application Publication
(10) Pub. No.: US 2026/0029635 A1
(43) Pub. Date: Jan. 29, 2026

(54) OPTICAL APPARATUS AND CONTROL METHOD OF THE SAME

(71) Applicant: Lasertec Corporation, Yokohama (JP)

(72) Inventors: Kazuya TSURUMOTO, Yokohama-shi (JP); Nao SATO, Yokohama-shi (JP); Kenshi ISHIWATARI, Yokohama-shi (JP)

(21) Appl. No.: 19/280,709

(22) Filed: Jul. 25, 2025

(30) Foreign Application Priority Data
Jul. 25, 2024 (JP) 2024-119622

(51) Int. Cl. G02B 21/24; G02B 21/08; G02B 21/26

(52) U.S. Cl. CPC G02B 21/245; G02B 21/082; G02B 21/26

(57) ABSTRACT

A light source emits illumination light. An objective lens focuses the illumination light on a sample. A first detector detects reflected light at a location anterior to the focal plane of the sample. A second detector detects the reflected light at a location posterior to the focal plane of the sample. A third light detector detects the incident reflected light. A beam splitter splits the reflected light into the first and second light detectors and the third light detector. A focus adjustment mechanism adjusts a focus position of the objective lens, based on a detection result from the first and second light detectors. A optical path length adjustment mechanism is provided between the beam splitter and the first and second light detectors, and adjusts an optical distance between the beam splitter and the first and second light detectors to a value corresponding to a magnification of the objective lens.

### INCORPORATION BY REFERENCE

This application is based upon and claims the benefit of priority from Japanese patent application No. 2024-119622, filed on Jul. 25, 2024, the disclosure of which is incorporated herein in its entirety by reference for all purposes.

### BACKGROUND

The present disclosure relates to an optical apparatus and a control method of the same.

In image capturing apparatuses using an optical system such as a camera or a microscope, focus detection is widely used for automatically focusing on a subject. As such focus detection, front focus/rear focus-type focus detection is known (Japanese Unexamined Patent Application Publication No. 2020-64127).

In front focus/rear focus, two light detectors are disposed such that the light-receiving surface of one light detector is located in front of the focal point of a secondary light beam from a sample and the light-receiving surface of the other light detector is located behind the focal point. The intensity of the secondary light beam detected by the two detectors is monitored while changing a distance of an objective lens relative to the sample. A position of the objective lens when both detectors are in a predetermined balance is detected as a position at which the objective lens is in focus on the sample.

### SUMMARY

In the above front focus/rear focus, a distance between two positions of the objective lens at which each of the two light detectors detects maximum light intensity is generally referred to as pull-in range. This pull-in range is known to be wide when magnification of the objective lens is low and narrow when the magnification of the objective lens is high.

Therefore, when an objective lens with high magnification is used, a range in which the objective lens can be moved between front focus and rear focus in order to find the position at which the objective lens is in focus is small. This makes it difficult to detect the position at which the objective lens is in focus.

An optical apparatus according to the present disclosure includes: one or more processors configured to execute a program stored in a memory; a light source configured to emit illumination light; an objective lens configured to focus the illumination light on a sample; a first detector configured to detect a secondary light beam generated by illuminating the sample with the illumination light at a location anterior to the focal plane of the sample; a second detector configured to detect the secondary light beam at a location posterior to the focal plane of the sample; a third detector configured to detect the secondary light beam incident via the objective lens; a beam splitter configured to split the secondary light beam into the first and second detectors and the third detector; a focus adjustment mechanism configured to adjust a focus position of the objective lens in response to control instructions, wherein the one or more processors are further configured to generate the control instructions for the focus adjustment mechanism based on detection results from the first and second detectors; and an optical path length adjustment mechanism located between the beam splitter and the first and second detectors, and configured to adjust an optical path length in accordance with a magnification of the objective lens.

A control method of an optical apparatus according to the present disclosure, the optical apparatus including: a light source configured to emit illumination light; an objective lens configured to focus the illumination light on a sample; a first detector configured to detect a secondary light beam generated by illuminating the sample with the illumination light at a location anterior to the focal plane of the sample; a second detector configured to detect the secondary light beam at a location posterior to the focal plane of the sample; a third detector configured to detect the secondary light beam incident via the objective lens; a beam splitter configured to split the secondary light beam into the first and second detectors and the third detector; an optical path length adjustment mechanism located between the beam splitter and the first and second detectors; the control method comprising: performing focus adjustment of the objective lens with respect to the sample based on detection results from the first and second detectors; and adjusting an optical path length between the beam splitter and the first and second detectors to a value corresponding to a magnification of the objective lens by controlling the optical path length adjustment mechanism.

According to the present disclosure, focus alignment of an objective lens can be performed efficiently regardless of a magnification of the objective lens.

The above and other objects, features and advantages of the present disclosure will become more fully understood from the detailed description given hereinbelow and the accompanying drawings.

### BRIEF DESCRIPTION OF DRAWINGS

FIG. 1 is a diagram schematically showing a configuration of an optical apparatus according to a first embodiment;

FIG. 2 is a diagram schematically showing a relationship between a position of an objective lens and an intensity of reflected light detected by a light detector;

FIG. 3 is a diagram schematically showing an optical path in the optical apparatus when a magnification of the objective lens is high;

FIG. 4 is a diagram schematically showing an optical path in the optical apparatus when the magnification of the objective lens is low;

FIG. 5 is a diagram schematically showing a configuration of an optical apparatus according to a second embodiment, and

FIG. 6 is a diagram showing the configuration example of the computer for realizing the focus control unit, the lens control unit, and the controls means thereof.

### DESCRIPTION OF EMBODIMENTS

Hereinafter, specific configurations of embodiments will be described with reference to the drawings. The following description shows preferred embodiments of the present disclosure, and the scope of the present disclosure is not limited to the following embodiments. In the following description, components denoted by the same reference numerals indicate substantially similar content.

### First Embodiment

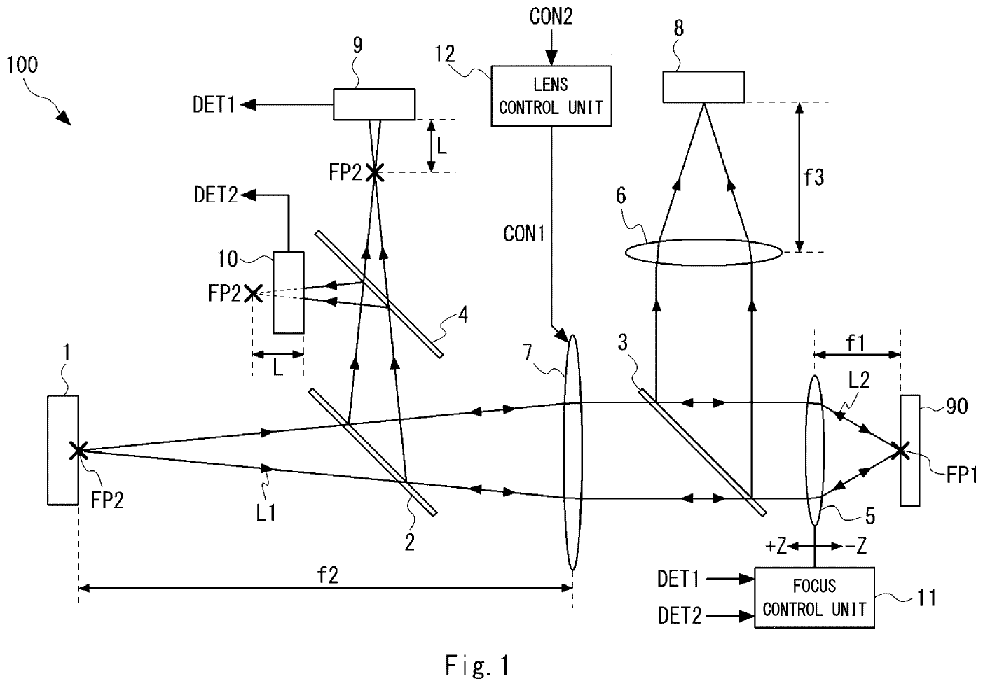

An optical apparatus according to a first embodiment will be described. The optical apparatus according to the present embodiment is configured as including an optical system that images a sample being a target. FIG. 1 is a diagram schematically showing a configuration of the optical apparatus according to the first embodiment. An optical apparatus 100 includes a light source 1, beam splitters 2 to 4, an objective lens 5, a lens 6, an adjustment lens 7, light detectors 8 to 10, a focus control unit 11, and a lens control unit 12.

The light source 1 is configured as a point light source and emits illumination light L1. The light source 1 may, for example, be provided with a laser element and a slit on a path of laser light emitted from the laser element. Light passing through the slit may be emitted as the illumination light L1. In FIG. 1 showing the configuration of the optical apparatus and in the following figures, the path of the light in the optical apparatus is indicated by directional lines.

The illumination light L1 is radiated onto a sample 90 via the beam splitter 2, the adjustment lens 7, the beam splitter 3, and the objective lens 5. Reflected light L2 generated by irradiating the sample 90 with the illumination light L1 is incident on the beam splitter 3 via the objective lens 5.

Hereinafter, the reflected light L2 from the sample 90 is also referred to as a secondary light beam generated by illuminating the sample 90 with the illumination light L1. However, the secondary light beam is not limited to reflected light. The secondary light beam may be various types of light beams, such as reflected light, transmitted light, scattered light, or fluorescence from the sample 90 generated by illuminating the sample 90 with the illumination light L1.

The objective lens 5 is configured to be drivable by the focus control unit 11 along an emission direction of the illumination light L1 to the sample 90 so that a focal point FP1 is aligned with the sample 90. Hereinafter, the emission direction of the illumination light L1 is also referred to as a Z-direction. A focal length of the objective lens 5 is f1.

The beam splitter 3 splits the incident reflected light L2 toward the lens 6 of a detection optical system and the adjustment lens 7.

The reflected light L2 incident on the lens 6 is focused by the lens 6 and is incident on the light detector 8. Here, a focal length of the lens 6 is f3. The light detector 8 is configured as, for example, a sensor on which light-receiving elements are two-dimensionally arrayed, such as a charge-coupled device (CCD) or a complementary metal-oxide-semiconductor (CMOS) sensor, and acquires a profile of the reflected light L2 and an image of the sample 90, required for inspection of the sample 90. The light detector 8 is provided at a position conjugate to a position at which the illumination light L1 is focused on the sample 90 by the objective lens 5. Note that the light detector 8 is also referred to as a third detection unit or a third detection means.

In the present configuration, an optical system that radiates the illumination light L1 from the light source 1 to the sample 90 and guides the reflected light L2 from the sample 90 to the light detector 8 may be configured as a confocal optical system in order to enhance the quality of the image of the sample 90 acquired by the light detector 8.

The reflected light L2 incident on the adjustment lens 7 is partially reflected by the beam splitter 2 and is incident on the beam splitter 4. The beam splitter 4 splits the incident reflected light L2 toward each of the light detectors 9 and 10.

In the present configuration, a focal point FP2 of the adjustment lens 7 coincides with an emission point of the illumination light L1 from the light source 1. Here, a focal length of the adjustment lens 7 is f2. Therefore, the focal point FP2 of the reflected light L2 split by the beam splitter 4 is at a position conjugate to the emission point of the illumination light L1 of the light source 1. Note that hereinafter, the focal length f2 of the adjustment lens 7 is also referred to as a first focal length.

The light detectors 9 and 10 and the focus control unit 11 constitute a front focus/rear focus-type focus alignment control mechanism that drives the objective lens 5 in the Z-direction so that the focal point FP1 of the objective lens 5 is aligned with the sample 90. The focus control unit 11 is also referred to as a focus adjustment mechanism. The light detectors 9 and 10 are, for example, configured as light-receiving elements such as photodiodes, and can detect an intensity of incident reflected light L2. Note that the light detector 9 is also referred to as a second detection unit or a second detection means, and the light detector 10 is also referred to as a first detection unit or a first detection means.

The light detectors 9 and 10 are disposed at different optical distances from the beam splitter 4. In this example, the optical distance between the light detector 9 and the beam splitter 4 is longer than the optical distance between the light detector 10 and the beam splitter 4. Therefore, the light detector 9 is disposed at a position farther than the focal point FP2 of the reflected light L2 (rear focus position). Thus, the light detectors 9 detects the reflected light L2 at a location anterior to the focal plane of the sample 90 (i.e., the focal point FP2). The light detector 10 is disposed at a position closer than the focal point FP2 of the reflected light L2 (front focus position). Thus, the light detectors 10 detects the reflected light L2 at a location posterior to the focal plane of the sample 90 (i.e., the focal point FP2)

The light detectors 9 and 10 respectively output detection signals DET1 and DET2 indicating the intensity of the received reflected light L2 to the focus control unit 11.

The focus control unit 11 is configured as a drive mechanism that can adjust the position of the objective lens 5 in the Z-direction so that the focal point FP1 of the objective lens 5 is aligned with the sample 90, based on the detection signals DET1 and DET2. With this, the focus control unit 11 can drive the objective lens 5 to the position at which the focal point FP1 is aligned with the sample 90. The focus control unit 11 can, for example, use various types of drive mechanisms including driving components such as motors.

The adjustment lens 7 and the lens control unit 12 are configured as optical distance adjustment means or an optical path length adjustment mechanism that can adjust an optical distance between the light detectors 9 and 10.

The adjustment lens 7 is configured as a varifocal lens that can adjust the focal length f2 at an emission side of the reflected light L2, that is, at a side at which the beam splitter 2 is disposed. The adjustment lens 7 may be configured as a zoom lens in which a plurality of lenses are combined. The adjustment lens 7 may be configured as a single lens with a variable focal length.

The lens control unit 12 receives the control signal CON2 indicating the magnification of the objective lens 5, and controls the focal length f2 of the adjustment lens 7 via a control signal CON1 in accordance with the magnification of the objective lens 5.

The adjustment lens 7 is not limited to a single lens. For example, the lens control unit 12 may be configured to select a lens corresponding to the objective lens 5 from a plurality of lenses with different focal lengths as the adjustment lens 7, dispose the selected lens between the beam splitter 3 and the light detectors 9 and 10.

Next, front focus/rear focus-type focus alignment control will be described. As described above, the optical apparatus 100 is configured so that the focal point FP2 of the reflected light L2 is rear focus with respect to the light detector 9 and front focus with respect to the light detector 10. In the front focus/rear focus-type focus alignment control, the amount of light detected by the light detectors 9 and 10 changes as the position of the objective lens 5 with respect to sample 90 in the Z-direction changes.

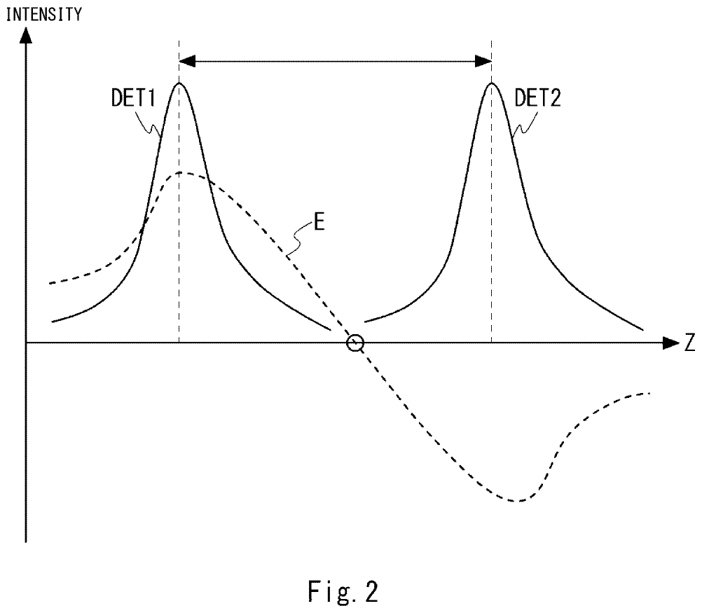

FIG. 2 is a diagram schematically showing a relationship between the position of the objective lens 5 in the Z-direction and the intensity of the reflected light L2 detected by the light detectors 9 and 10. Since the position of the focal point FP2 of reflected light L2 differs with respect to the light detectors 9 and 10, if the position of the objective lens 5 in the Z-direction is a horizontal axis as shown in FIG. 2, a peak of the detection signal DET1 indicating the intensity of the reflected light L2 detected by light detector 9 and a peak of the detection signal DET2 indicating the intensity of the reflected light L2 detected by the light detector 10 are at distant positions from each other. In the front focus/rear focus-type focus alignment control, a distance between the peak of the detection signal DET1 and the peak of the detection signal DET2 is generally referred to as a pull-in range D.

When the light detectors 9 and 10 are disposed at appropriate positions, a position at which an intensity of the detection signal DET1 and an intensity of the detection signal DET2 are balanced indicates a state in which the focal point FP1 of the objective lens 5 is aligned with the sample 90. Therefore, the focus control unit 11 can drive the objective lens 5 to the position at which the focal point FP1 is aligned with the sample 90 by monitoring the detection signals DET1 and DET2.

In this case, the focus control unit 11 may detect a position at which an error signal E based on a difference between the detection signals DET1 and DET2 is 0 as the position at which the focal point FP1 of the objective lens 5 is aligned with the sample 90 (may be referred to as an in-focus position). The error signal E may be defined by, for example, the following equation.

$$E = ( DET 1 - DET 2 ) / ( DET 1 + DET 2 )$$

Next, an influence of the magnification of the objective lens 5 on the front focus/rear focus-type focus alignment control will be described. A general optical system does not have a configuration in which the adjustment lens 7 is provided and a focal length thereof is changed as in the optical apparatus 100. Therefore, the above-described pull-in range D changes upon changing the magnification of the objective lens 5. When the magnification of the objective lens 5 is high (for example, 100×), the pull-in range D is narrower than when the magnification of the objective lens 5 is low (for example, 10×). This will be described in detail below.

The pull-in range D is determined by an optical distance L between the light detectors 9 and 10 and the focal point FP2 of the reflected light L2 incident on the light detectors 9 and 10, the focal length f1 of the objective lens 5, and the focal length f2 at a side at which the light source 1 of the adjustment lens 7 is disposed. Note that hereinafter, the focal length f1 of the objective lens 5 is also referred to as a second focal length.

$$D = \frac{L}{2 α} \qquad [ Mathematical formula 1 ]$$

where, α is defined by the following equation.

$$α = {( \frac{f 2}{f 1} )}^{2} \qquad [ Mathematical formula 2 ]$$

In a general optical system, a fixed-focus relay lens or the like is disposed at a position of the adjustment lens 7. That is, only the focal length f1 of the objective lens 5 is changed upon changing the magnification of the objective lens 5 in a state in which the focal length f2 is fixed. Thus, since a value of α changes, the pull-in range D fluctuates.

When the magnification of the objective lens 5 is low, that is, the focal length f1 is long, α is small. As a result, the pull-in range D is large. On the other hand, when the magnification of the objective lens 5 is high, that is, the focal length f1 is short, α is large. As a result, the pull-in range D is small. In other words, in a front focus/rear focus-type detection mechanism in a general optical apparatus, the higher the magnification of the objective lens 5 is, the narrower the pull-in range D between the front focus and the rear focus is.

Thus, since a range in which the objective lens 5 can be moved in the Z-direction between the front focus and the rear focus while ensuring the effectiveness of the front focus/rear focus-type focus alignment control is small, high accuracy is required for alignment of the objective lens 5 to the in-focus position. As a result, when the magnification of the objective lens 5 is high, problems may occur such as the focus alignment control taking time and the accuracy of the focus alignment deteriorating.

In order to handle the difficulty of the focus alignment control via the magnification of the objective lens 5 described above, the optical apparatus 100 according to the present embodiment is configured to prevent or otherwise suppress the fluctuation of the pull-in range D by changing the magnification of the objective lens 5, by suitably controlling the focal length f2 of the adjustment lens 7.

Control of the focal length f2 of the adjustment lens 7 of the optical apparatus 100 will be described. The lens control unit 12 instructs the adjustment lens 7 via the control signal CON1 to have the focal length f2 that allows setting the value of αto a desired value when the magnification of the objective lens 5 indicated by the control signal CON2 is applied. With this, the focal length f2 of the adjustment lens 7 can be set to a desired focal length corresponding to the magnification of the objective lens 5 indicated by the control signal CON2.

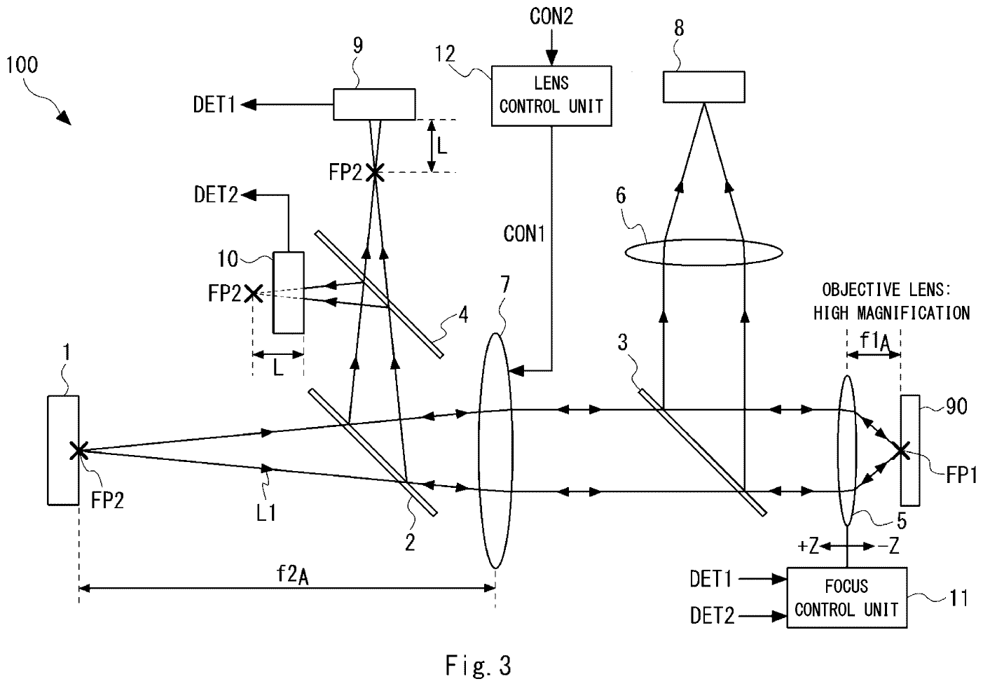

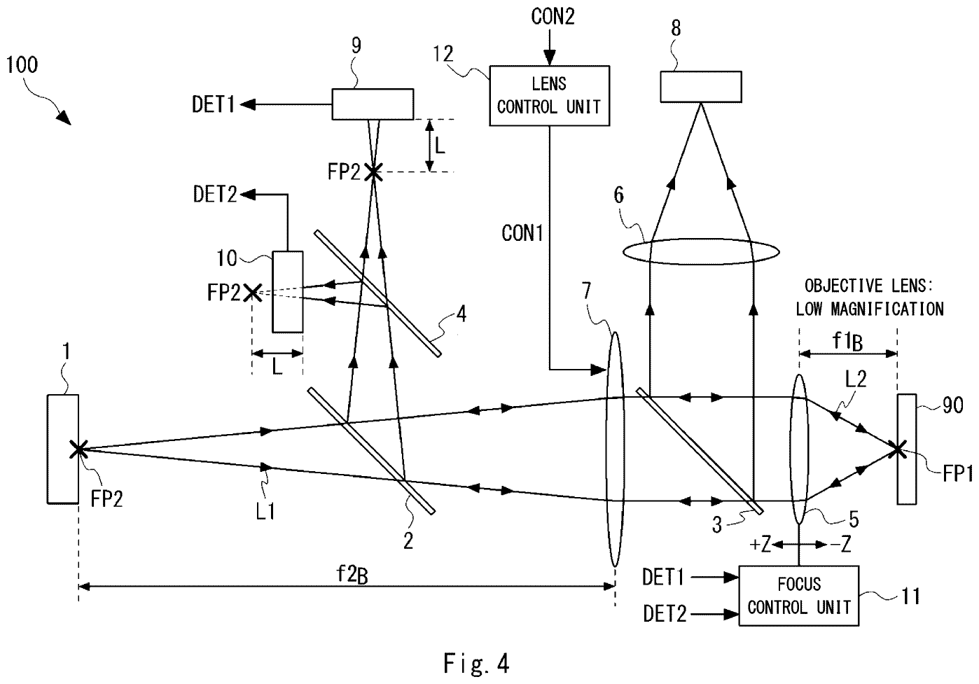

FIG. 3 is a diagram schematically showing an optical path in the optical apparatus 100 when the magnification of the objective lens 5 is high. FIG. 4 is a diagram schematically showing an optical path in the optical apparatus 100 when the magnification of the objective lens 5 is low. In FIG. 3, the focal length of the magnification objective lens 5 with high magnification is f1_{A} and the focal length of the adjustment lens 7 is f2_{A}. In FIG. 4, the focal length of the objective lens 5 with low magnification is f1_{B} and the focal length of the adjustment lens 7 is f2_{B}. The focal length f2_{A} of the adjustment lens 7 and the focal length f2_{B} of the adjustment lens 7 both coincide with the emission point of the illumination light L1 from the light source 1.

In FIGS. 3 and 4, the position of the adjustment lens 7 is different for the sake of description, but this does not necessarily mean that the position of the adjustment lens 7 is actually different. When the adjustment lens 7 is configured as a varifocal lens such as a zoom lens that can change focus without changing its position and shape, the position of the adjustment lens 7 does not need to change even when the magnification of the objective lens 5 is changed.

When the magnification of the objective lens 5 is high, the lens control unit 12 controls the adjustment lens 7 so that the focal length f2_{A} becomes shorter, as shown in FIG. 3. When the magnification of the objective lens 5 is low, the lens control unit 12 controls the adjustment lens 7 so that the focal length f2_{B} becomes longer, as shown in FIG. 4.

In this case, the lens control unit 12 preferably instructs the adjustment lens 7 to have the focal length f2, so that a can be maintained at a constant value regardless of the magnification of the objective lens 5, that is, a ratio of the focal length f1 of the objective lens 5 to the focal length f2 of the adjustment lens 7 can be maintained at a constant value. With this, the pull-in range D can be maintained at a constant value.

Even when α cannot be maintained at a constant set value via the magnification of the objective lens 5, the lens control unit 12 preferably instructs the adjustment lens 7 to have the focal length f2, so that a is a value within a predetermined range approximating the set value as much as possible, that is, so that the ratio of the focal length f1 of the objective lens 5 to the focal length f2 of the adjustment lens 7 is a value within a predetermined range. With this, the pull-in range D can be set to a value greater than a predetermined value.

Note that the light detector 8 used for imaging the sample 90 receives the reflected light L2 from the sample 90 without going through the adjustment lens 7. Therefore, an image of the sample 90 can be acquired regardless of a change in the magnification of the objective lens 5.

Therefore, according to the present configuration, the pull-in range D can be maintained at a constant value or otherwise within a desired range by suitably changing the focal length f2 of the adjustment lens 7, even when the magnification of the objective lens 5 is changed. With this, the focal point FP1 of the objective lens 5 can be efficiently aligned with the sample 90 regardless of the magnification of the objective lens 5.

### Second Embodiment

An optical apparatus according to a second embodiment will be described. The optical apparatus according to the present embodiment is configured as further including a magnification change mechanism for the objective lens.

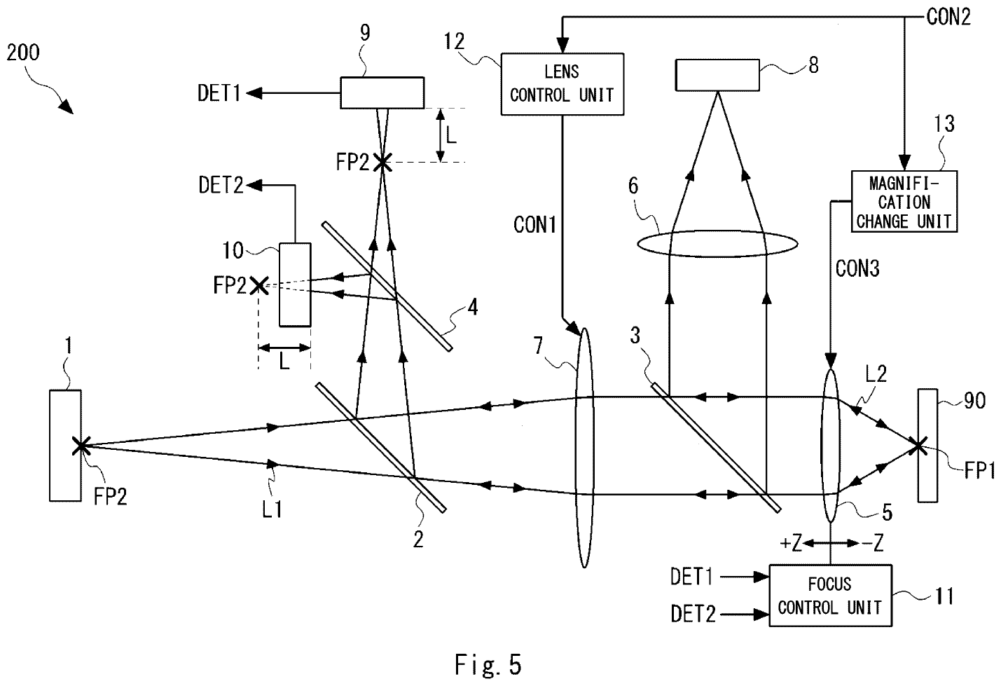

FIG. 5 is a diagram schematically showing a configuration of an optical apparatus 200 according to the second embodiment. As compared to the optical apparatus 100 according to the first embodiment, the optical apparatus 200 further includes a magnification change unit 13. The magnification change unit 13 switches the magnification of the objective lens 5 in accordance with the control signal CON2 indicating the magnification of the objective lens 5 provided by a user or the like.

When the magnification can be changed with the same lens such as when the objective lens 5 is configured as a variable magnification lens, the magnification change unit 13 may switch the magnification of the objective lens 5 by providing the objective lens 5 with a control signal CON3, as shown in FIG. 5.

The magnification change unit 13 may be configured to use, as the objective lens 5, an objective lens selected from a plurality of objective lenses with different magnifications in accordance with the control signal CON2. For example, the magnification change unit 13 may include a mechanism to select, from a plurality of objective lenses attached to a revolver, an objective lens to be used as the objective lens 5 by driving a revolver.

According to the present configuration, the pull-in range D can be maintained at a constant value or otherwise within a desired range by suitably changing the focal length f2 of the adjustment lens 7 while automatically changing the magnification of the objective lens 5 in accordance with the control signal CON2. With this, the focal point FP1 of the objective lens 5 can be efficiently aligned with the sample 90 regardless of the magnification of the objective lens 5, similar to the first embodiment.

### OTHER EMBODIMENTS

The present disclosure has been described above with reference to the embodiments, but the present disclosure is not limited to the above-described embodiments. From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims. Each embodiment can be combined with other embodiments as appropriate. Hence, the first and second embodiments can be combined as desirable by one of ordinary skill in the art.

The configurations of the optical apparatuses described above are merely an example and other configurations are possible as long as the sample 90 is irradiated with the illumination light L1 emitted from the light source 1 and the secondary light beam from the sample 90 can be detected by the light detectors 8 to 10. For example, the optical apparatuses according to the above embodiments are described as including a refractive optical system, but the optical apparatuses may be configured as including a catadioptric optical system or a reflective optical system and a means for adjusting a focal length of the secondary light beam similar to the adjustment lens 7, as necessary.

The focus control unit 11 is described as driving the objective lens 5 to the position at which the focal point FP1 is aligned with the sample 90, but is not limited thereto. The focus control unit 11 may cause a relative position of the sample 90 to the objective lens 5 to vary, or may drive a stage or the like that holds the sample 90.

In the above-described embodiment, the optical apparatus according to the present disclosure is described mainly as a hardware configuration but is not limited thereto. It is also possible to realize the optical apparatus according to the present disclosure by causing a computer to execute a computer program for performing freely-selected processing. This processing may be realized by causing a computer including at least one processor (for example, microprocessor, CPU, GPU, MPU, or digital signal processor (DSP)) execute a program. To be specific, one or more programs including a set of commands for causing the computer to perform an algorithm related to this transmission signal processing or reception signal processing may be created, and the program may be supplied to the computer.

The computer program can be stored and supplied to the computer, by using various types of non-transitory computer-readable media. The non-transitory computer-readable media include various types of tangible storage media. Examples of the non-transitory computer-readable media include magnetic recording media (for example, flexible disks, magnetic tape, or hard disk drives), magneto-optical recording media (for example, magneto-optical disks), CD read-only memory (ROM), CD-R, CD-R/W, CD-R/W, and semiconductor memory (for example, mask ROM, programmable ROM (PROM), erasable PROM (EPROM), flash ROM, random-access memory (RAM)). The program can be supplied to the computer via various types of transitory computer-readable media. Examples of the transitory computer-readable media include electrical signals, optical signals, and electromagnetic waves. The transitory computer-readable media can supply the program to the computers via a wired or wireless communication path, such as an electric wires and optical fiber.

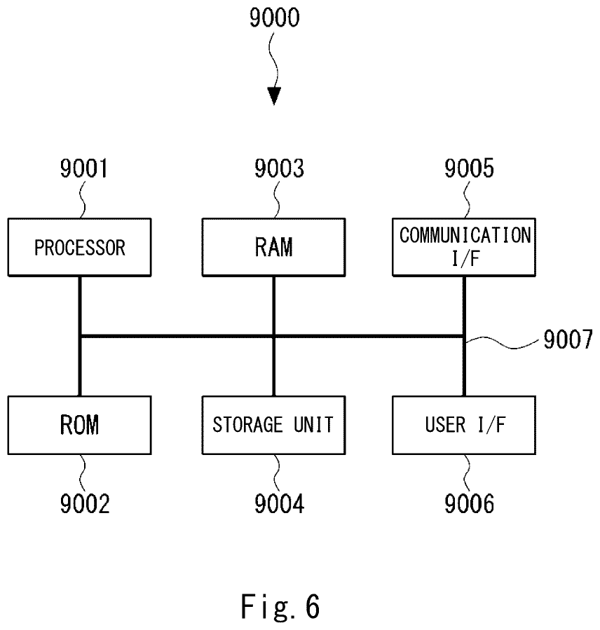

Hereinafter, a configuration example is shown of a computer for realizing the focus control unit 11, the lens control unit 12, and controls means thereof. FIG. 6 is a diagram showing the configuration example of the computer for realizing the focus control unit 11, the lens control unit 12, and the controls means thereof. The focus control unit 11, the lens control unit 12, and the controls means thereof can be realized by a computer 9000, such as a dedicated computer or a personal computer (PC). However, the computer need not be a single physical apparatus, but may be a plurality of apparatuses when executing distributed processing. As shown in FIG. 6, the computer 9000 includes, for example, a processor 9001, a read-only memory (ROM) 9002, a random-access memory (RAM) 9003, a storage unit 9004, a communication interface 9005, and a user interface 9006.

The processor 9001, the ROM 9002, the RAM 9003, the storage unit 9004, the communication interface 9005, and the user interface 9006 are communicably connected via a bus 9007. Note that description of OS software or the like for causing the computer to operate is omitted but is introduced in the computer 9000 as appropriate.

The ROM 9002 consists of, for example, a non-volatile semiconductor storage apparatus. The ROM 9002 stores information such as various programs used by the computer 9000.

The storage unit 9004 consists of, for example, various storage apparatuses such as hard disks or solid-state disks. The storage unit 9004 is not limited to the storage apparatuses installed in the computer 9000, but may be external storage apparatuses of the computer 9000. The external storage apparatuses may be a cloud storage or the like connected the computer 9000 via various communication means, for example, a network. The storage unit 9004 stores information such as various programs or data used by the computer 9000.

The RAM 9003 consists of, for example, a volatile semiconductor storage apparatus. In the RAM 9003, information such as programs or data used by the processor 9001 is loaded from one or both of the ROM 9002 and the storage unit 9004 as appropriate.

The processor 9001 may consist of, for example, a central processing unit (CPU). The processor 9001 may include not only a CPU, but also a graphics processing unit (GPU). The GPU is suitable for performing routine processing in parallel, and can also enhance processing speed as compared to the CPU, by applying the GPU to processing in a neural network, for example. The processor 9001 executes various processing based on various programs stored in the ROM 9002 or various programs and data held in the RAM 9003 as appropriate. The processor 9001 may also store data generated by the processing in the RAM 9003, the storage unit 9004, or the like as appropriate.

The communication interface 9005 is an interface that connects the computer 9000 to a communication network, such as the Internet, an intranet, or the like, via various wired or wireless communication means. With this, the computer 9000 can communicate with another apparatus, a system, a sensor, and the like connected to the communication network.

The user interface 9006 includes, for example, a display part, a speech output part, or the like that provides information for a user to recognize via a display apparatus, via speech, or the like. The user interface 9006 includes an input part that allows information to be input to the computer 9000 through a user operation, such as a keyboard, a mouse, or a touch panel. The user interface 9006 may also include equipment such as a sensor that acquires information useful to the user.

Here, the computer 9000 has been described here as one apparatus, but this is merely an example. The computer 9000 may consist of a plurality of apparatuses that are physically separated. Part of the plurality devices may be transportable devices, and others may be stationary apparatuses.

The present disclosure has been described above with reference to the embodiments, but the present disclosure is not limited to the above-described embodiments. Various changes can be made to the configurations, contents, and the like of the present disclosure that can be understood by those skilled in the art within the scope of the present disclosure. However, the embodiments can be combined with the other embodiments as appropriate.

Each drawing is merely an example for describing one or more embodiments. Each drawing need not be associated with only one particular embodiment, but may be associated with one or more other embodiments. As can be understood by one skilled in the art, various features or steps described with reference to any one of the drawings may be combined with features or steps described in one or more other drawings to produce, for example, an embodiment that is not explicitly shown or described. Not all of the features or steps illustrated in any one of the drawings for describing an embodiment are necessarily essential, and some features or steps may be omitted. The order of the steps described in any of the drawings may be changed as appropriate.

What is claimed is:

1. An optical apparatus comprising:
one or more processors configured to execute a program stored in a memory;
a light source configured to emit illumination light;
an objective lens configured to focus the illumination light on a sample;
a first detector configured to detect a secondary light beam generated by illuminating the sample with the illumination light at a location anterior to the focal plane of the sample;
a second detector configured to detect the secondary light beam at a location posterior to the focal plane of the sample;
a third detector configured to detect the secondary light beam incident via the objective lens;
a beam splitter configured to split the secondary light beam into the first and second detectors and the third detector;
a focus adjustment mechanism configured to adjust a focus position of the objective lens in response to control instructions, wherein the one or more processors are further configured to generate the control instructions for the focus adjustment mechanism based on detection results from the first and second detectors; and
an optical path length adjustment mechanism located between the beam splitter and the first and second detectors, and configured to adjust an optical path length in accordance with a magnification of the objective lens.

2. The optical apparatus according to claim 1, wherein the optical path length adjustment mechanism includes a varifocal lens configured to be able to adjust a first focal length at side at which the first and second detectors are disposed, and controls the first focal length of the varifocal lens to a value corresponding to the magnification of the objective lens.

3. The optical apparatus according to claim 2, wherein the varifocal lens is configured as a zoom lens consisting of a combination of a plurality of lenses.

4. The optical apparatus according to claim 2, wherein the optical path length adjustment mechanism controls the first focal length so that a pull-in range between front focus and rear focus is greater than a predetermined value due to a change in the magnification of the objective lens, or so that the pull-in range remains constant regardless of a change in the magnification of the objective lens.

5. The optical apparatus according to claim 4, wherein the optical path length adjustment mechanism controls the first focal length so that a ratio of the first focal length to a second focal length of the objective lens is within a predetermined range, or so that the ratio remains constant regardless of a change in the magnification of the objective lens.

6. The optical apparatus according to claim 1, wherein the optical path length adjustment mechanism includes a plurality of lenses with different focal lengths, and a lens with a focal length corresponding to the magnification of the objective lens selected from the plurality of lenses is disposed between the beam splitter and the first and second detectors.

7. The optical apparatus according to claim 1, wherein an optical system including at least the light source and the third detector constitutes a confocal optical system.

8. The optical apparatus according to claim 1, wherein the third detector is provided at a position conjugate to a position at which the illumination light is focused on the sample by the objective lens.

9. The optical apparatus according to claim 1, further comprising a magnification changing mechanism configured to be able to change the magnification of the objective lens in accordance with information specifying the magnification of the objective lens,
wherein the optical path length adjustment mechanism controls an optical distance between the beam splitter and the first and second detectors so as to be a value corresponding to the magnification of the objective lens specified by the information.

10. A control method of an optical apparatus, the optical apparatus comprising:
a light source configured to emit illumination light;
an objective lens configured to focus the illumination light on a sample;
a first detector configured to detect a secondary light beam generated by illuminating the sample with the illumination light at a location anterior to the focal plane of the sample;
a second detector configured to detect the secondary light beam at a location posterior to the focal plane of the sample;
a third detector configured to detect the secondary light beam incident via the objective lens;
a beam splitter configured to split the secondary light beam into the first and second detectors and the third detector;
an optical path length adjustment mechanism located between the beam splitter and the first and second detectors;
the control method comprising:
performing focus adjustment of the objective lens with respect to the sample based on detection results from the first and second detectors; and
adjusting an optical path length between the beam splitter and the first and second detectors to a value corresponding to a magnification of the objective lens by controlling the optical path length adjustment mechanism.
